(19) United States
(12) Patent Application Publication
(10) Pub. No.: US 2024/0282677 A1
(43) Pub. Date: Aug. 22, 2024

(54) SEMICONDUCTOR DEVICE

(71) Applicant: Rohm Co., Ltd., Kyoto-shi (JP)

(72) Inventor: Masaaki MORI, Kyoto-shi (JP)

(21) Appl. No.: 18/650,970

(22) Filed: Apr. 30, 2024

Related U.S. Application Data
(63) Continuation of application No. PCT/JP2022/043515, filed on Nov. 25, 2022.

(30) Foreign Application Priority Data
Dec. 1, 2021 (JP) 2021-195180

(51) Int. Cl. H01L 23/495; H01L 23/00; H01L 23/29; H01L 23/31

(52) U.S. Cl. CPC H01L 23/49541; H01L 23/293; H01L 23/3142; H01L 23/49513; H01L 24/40; H01L 24/48; H01L 24/73; H01L 24/37; H01L 24/45; H01L 2224/37124; H01L 2224/40247; H01L 2224/45144; H01L 2224/48247; H01L 2224/73271; H01L 2924/13055; H01L 2924/13091

(57) ABSTRACT

A semiconductor device includes a semiconductor element; a first lead including a die pad portion and a first terminal portion, and a sealing resin. A first lead reverse surface is exposed from a second resin surface. The first terminal portion includes a first portion extending outward from a third resin surface to a first side in an x direction, a second portion located on a first side in a z direction relative to the first portion and used for mounting, and a third portion interposed between the first portion and the second portion. The second portion overlaps with the sealing resin as viewed in the z direction.

### TECHNICAL FIELD

The present disclosure relates to a semiconductor device.

### BACKGROUND ART

JP-A-2017-174951 discloses an example of a semiconductor device that includes a first lead including a first pad having a pad obverse surface and a pad reverse surface, a second lead, a third lead, a semiconductor element mounted on the pad obverse surface, and a sealing resin in contact with the pad obverse surface and covering the semiconductor element. The first lead, the second lead, and the third lead have a first terminal, a second terminal, and a third terminal, respectively, that extend in the same direction. The first terminal, the second terminal, and the third terminal are inserted into through-holes of a circuit board or the like, whereby the semiconductor device is mounted on the circuit board. In the case where the semiconductor device is attached to a heat sink, an insulating sheet may be provided between the pad reverse surface and the heat sink.

### BRIEF DESCRIPTION OF THE DRAWINGS

FIG. 1 is a perspective view showing a semiconductor device according to a first embodiment of the present disclosure.

FIG. 2 is a perspective view showing the semiconductor device according to the first embodiment of the present disclosure.

FIG. 3 is a perspective view showing main parts of the semiconductor device according to the first embodiment of the present disclosure.

FIG. 4 is a perspective view showing main parts of the semiconductor device according to the first embodiment of the present disclosure.

FIG. 5 is a plan view showing the semiconductor device according to the first embodiment of the present disclosure.

FIG. 6 is a bottom view showing the semiconductor device according to the first embodiment of the present disclosure.

FIG. 7 is a front view showing the semiconductor device according to the first embodiment of the present disclosure.

FIG. 8 is a plan view showing main parts of the semiconductor device according to the first embodiment of the present disclosure.

FIG. 9 is a bottom view showing main parts of the semiconductor device according to the first embodiment of the present disclosure.

FIG. 10 is a cross-sectional view along line X-X in FIG. 9.

FIG. 11 is a cross-sectional view along line XI-XI in FIG. 9.

FIG. 12 is a cross-sectional view along line XII-XII in FIG. 9.

FIG. 13 is a cross-sectional view along line XIII-XIII in FIG. 9.

FIG. 14 is a cross-sectional view showing a use state of the semiconductor device according to the first embodiment of the present disclosure.

FIG. 15 is a cross-sectional view showing a first variation of the semiconductor device according to the first embodiment of the present disclosure.

FIG. 16 is a cross-sectional view showing a use state of the first variation of the semiconductor device according to the first embodiment of the present disclosure.

FIG. 17 is a perspective view showing a second variation of the semiconductor device according to the first embodiment of the present disclosure.

FIG. 18 is a cross-sectional view showing the second variation of the semiconductor device according to the first embodiment of the present disclosure.

FIG. 19 is a perspective view showing a third variation of the semiconductor device according to the first embodiment of the present disclosure.

FIG. 20 is a cross-sectional view showing the third variation of the semiconductor device according to the first embodiment of the present disclosure.

FIG. 21 is a perspective view showing a fourth variation of the semiconductor device according to the first embodiment of the present disclosure.

FIG. 22 is a cross-sectional view showing the fourth variation of the semiconductor device according to the first embodiment of the present disclosure.

FIG. 23 is a perspective view showing a fifth variation of the semiconductor device according to the first embodiment of the present disclosure.

FIG. 24 is a cross-sectional view showing the fifth variation of the semiconductor device according to the first embodiment of the present disclosure.

FIG. 25 is a cross-sectional view showing a semiconductor device according to a second embodiment of the present disclosure.

FIG. 26 is a plan view showing main parts of a semiconductor device according to a third embodiment of the present disclosure.

FIG. 27 is a cross-sectional view showing a semiconductor device according to a fourth embodiment of the present disclosure.

### DETAILED DESCRIPTION OF EMBODIMENTS

The following describes preferred embodiments of the present disclosure in detail with reference to the drawings.

The terms such as “first”, “second” and “third” in the present disclosure are used merely for identification, and are not intended to impose orders on the items to which these terms refer.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Furthermore, the phrase “an object A overlaps with an object B as viewed in a certain direction” includes, unless otherwise specified, “an object A overlaps with the entirety of an object B” and “an object A overlaps with a portion of an object B”. Furthermore, the phrase “a plane A faces (a first side or a second side) in a direction B” is not limited to the case where the angle of the plane A with respect to the direction B is 90°, but also includes the case where the plane A is inclined to the direction B.

### First Embodiment

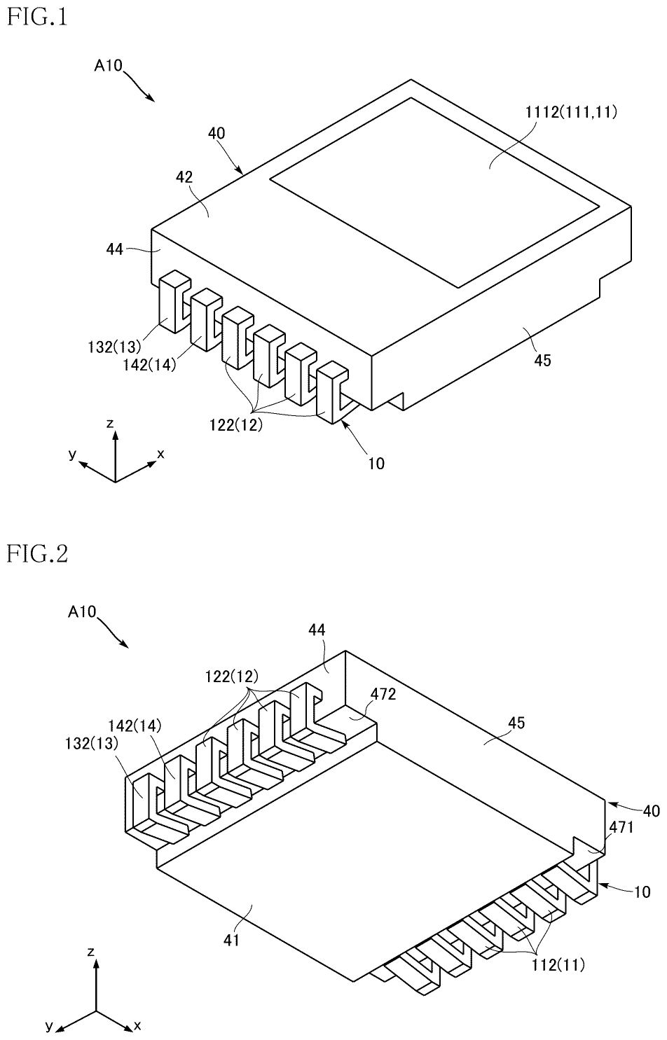

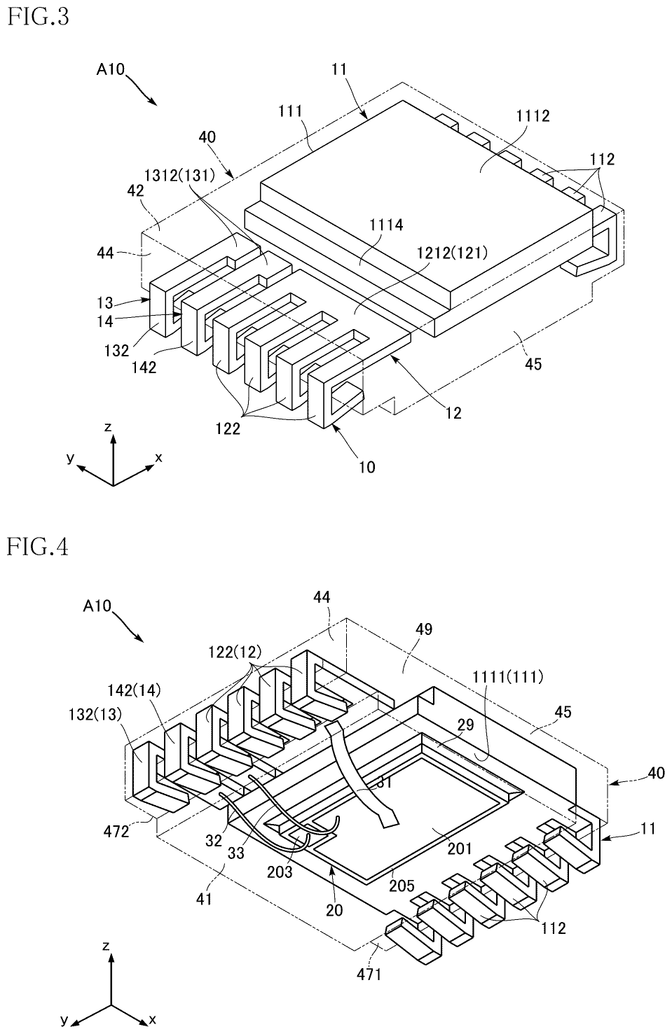

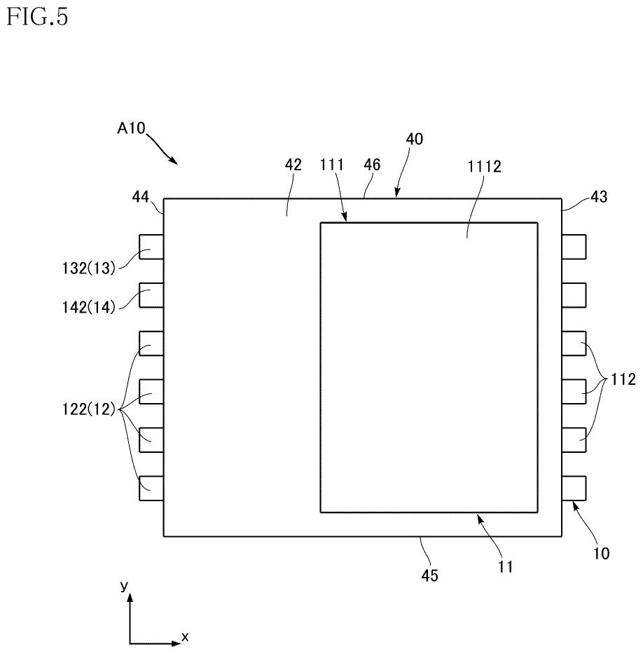

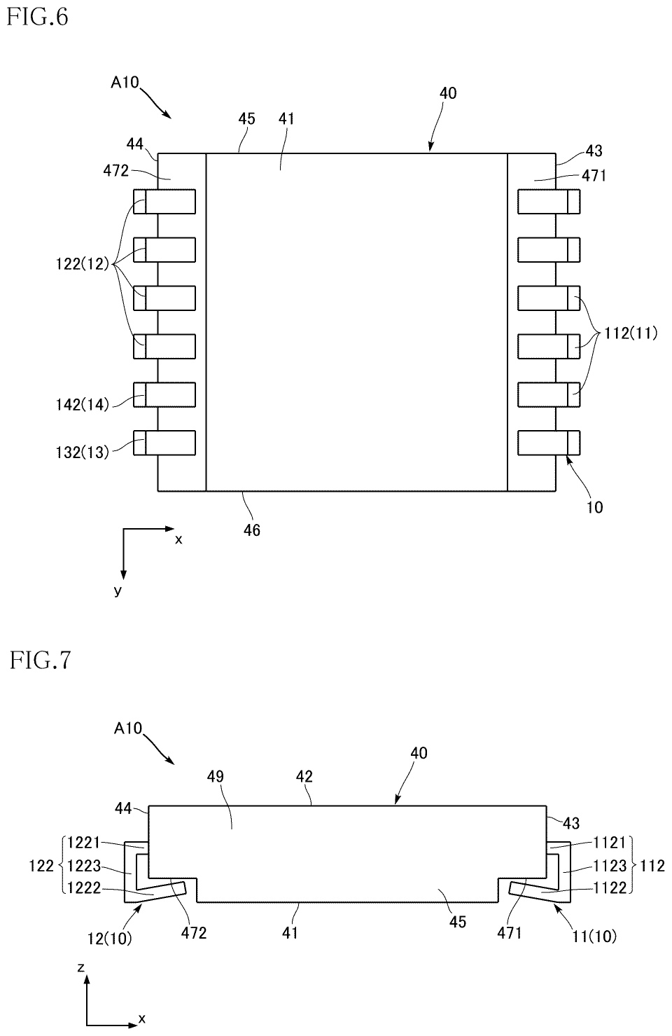

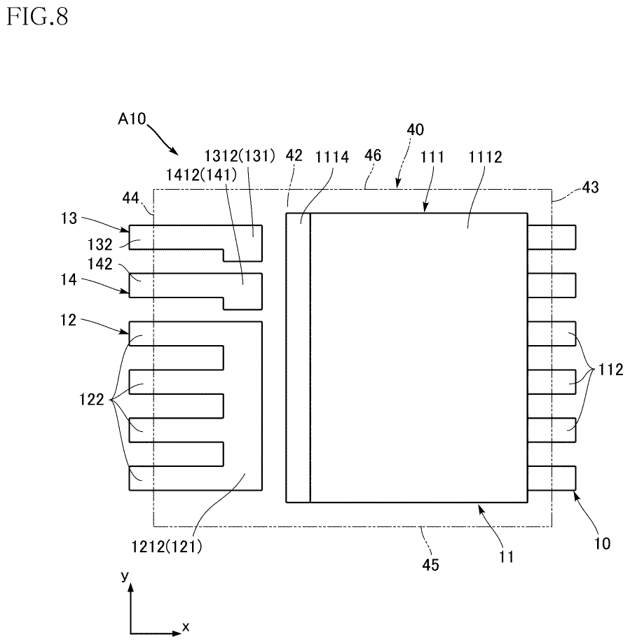

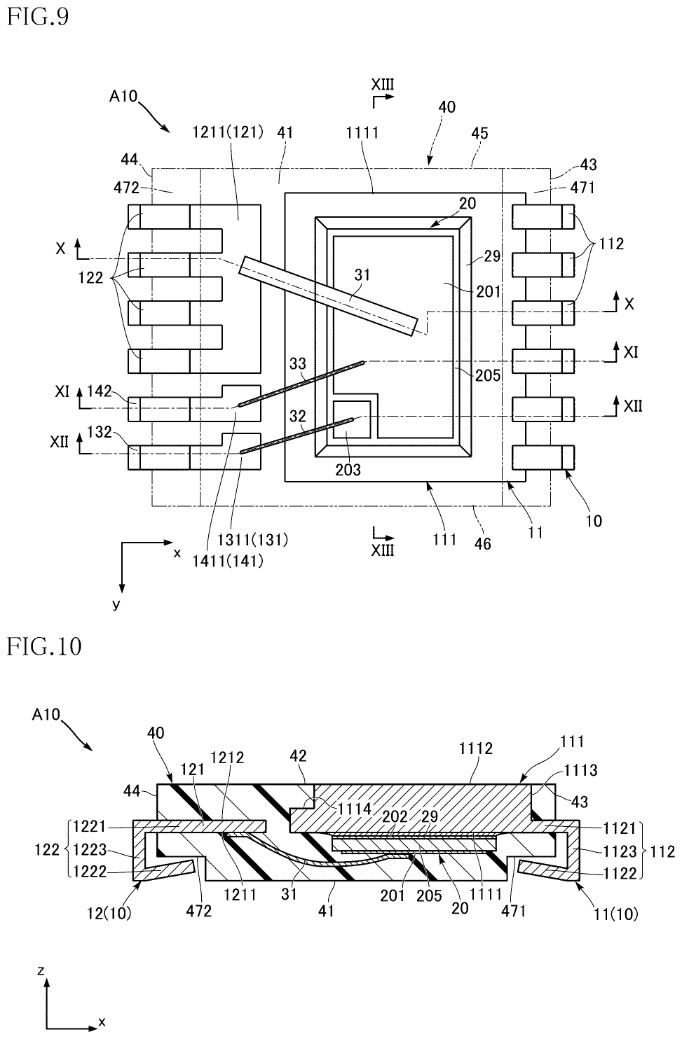

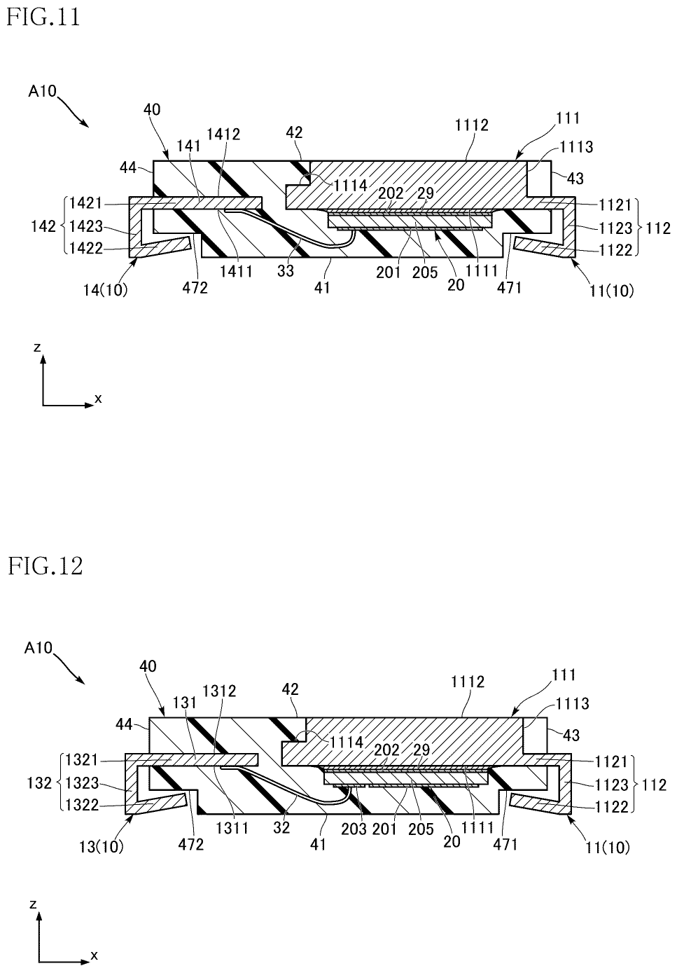

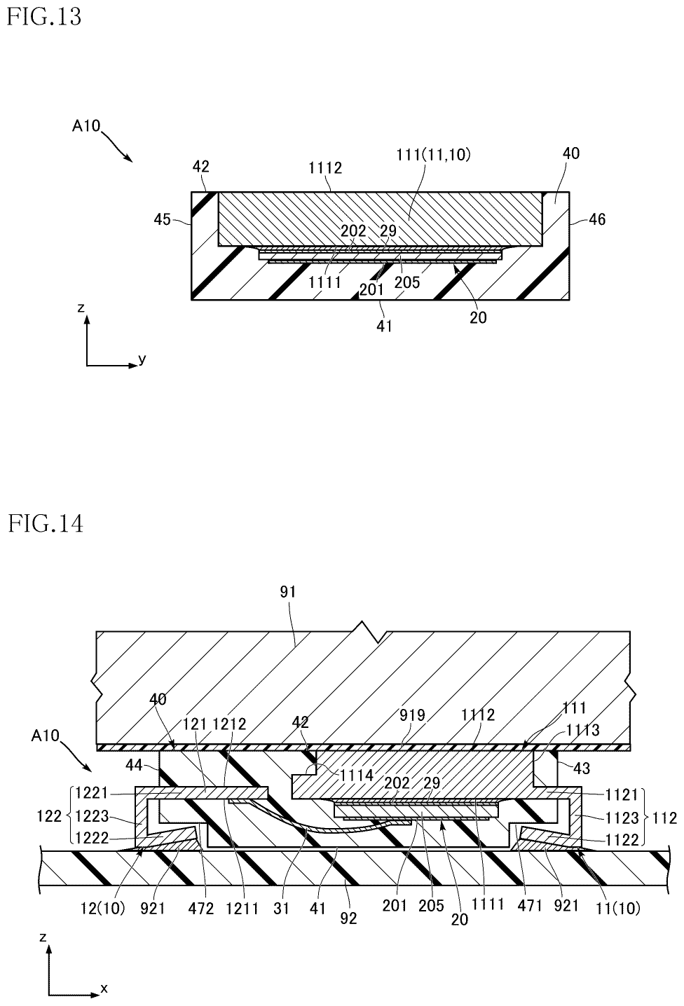

FIGS. 1 to 14 show a semiconductor device according to a first embodiment of the present disclosure. A semiconductor device A10 according to the present t embodiment includes a conductive member 10, a semiconductor element 20, connecting members 31, 32, and 33, and a sealing resin 40. In these figures, a z direction is an example of a “thickness direction”, an x direction is an example of a “first direction”, and a y direction is an example of a “second direction”.

### Conductive Member 10:

The conductive member 10 constitutes a conduction path to the semiconductor element 20. The conductive member 10 of the present embodiment includes a first lead 11, a second lead 12, a third lead 13, and a fourth lead 14. The material of the first lead 11, the second lead 12, the third lead 13, and the fourth lead 14 is not particularly limited, and may contain copper (Cu) or a copper alloy. Appropriate portions of the first lead 11, the second lead 12, the third lead 13, and the fourth lead 14 may be plated with a metal such as silver (Ag), nickel (Ni), or tin (Sn).

### First Lead 11:

As shown in FIGS. 1 to 14, the first lead 11 has a die pad portion 111 and a plurality of first terminal portions 112. The die pad portion 111 has a first lead obverse surface 1111, a first lead reverse surface 1112, and a first lead side surface 1113. The first lead obverse surface 1111 faces a first side in the z direction. The first lead reverse surface 1112 faces a second side in the z direction. The semiconductor element 20 is mounted on the first lead obverse surface 1111.

The first lead side surface 1113 is located between the first lead obverse surface 1111 and the first lead reverse surface 1112 in the z direction, and faces a first side in the x direction. The shape of the first lead side surface 1113 is not particularly limited, and in the illustrated example, is rectangular as viewed in the x direction.

The die pad portion 111 of the present embodiment further has a first intermediate surface 1114. The first intermediate surface 1114 is located between the first lead obverse surface 1111 and the first lead reverse surface 1112 in the z direction, and faces the first side in the z direction (the same side as the side that the first lead reverse surface 1112 faces).

The shape of the die pad portion 111 is not particularly limited. In the illustrated example, the die pad portion 111 has a rectangular shape as viewed in the z direction. The shape of each of the first lead obverse surface 1111 and the first lead reverse surface 1112 is not particularly limited, and in the illustrated example, is rectangular as viewed in the z direction.

The first terminal portions 112 are aligned in the y direction. Each of the first terminal portions 112 has a first portion 1121, a second portion 1122, and a third portion 1123.

The first portion 1121 is connected to a pad portion 121. The first portion 1121 extends from the first lead side surface 1113 of the die pad portion 111 toward the first side in the x direction, and in the illustrated example, is parallel (or substantially parallel) to an xy plane. The shape of the first portion 1121 is not particularly limited, and in the illustrated example, is rectangular as viewed in the z direction. In the present embodiment, the die pad portion 111 is larger than the first portion 1121 in the z direction. The first portion 1121 is spaced apart from the first lead reverse surface 1112 in the z direction, and in the illustrated example, is in contact with the first lead obverse surface 1111. One surface of the first portion 1121 is flush with the first lead obverse surface 1111.

The second portion 1122 is located on the first side in the z direction relative to the first portion 1121. The second portion 1122 is used when the semiconductor device A10 is surface-mounted on a circuit board or the like. The second portion 1122 extends in the x direction as viewed in the z direction.

The third portion 1123 is interposed between the first portion 1121 and the second portion 1122. The third portion 1123 extends from the first portion 1121 toward the first side in the z direction. In the illustrated example, the third portion 1123 is parallel (or substantially parallel) to the z direction. The shape of the third portion 1123 is not particularly limited, and in the illustrated example, is rectangular as viewed in the x direction.

The second portion 1122 extends from the third portion 1123 toward a second side in the x direction. In the illustrated example, the second portion 1122 is inclined to the x direction to become closer to the second side in the z direction as proceeding from the third portion 1123 toward the second side in the x direction. The second portion 1122 overlaps with the first portion 1121 as viewed in the z direction. The second portion 1122 also overlaps with the sealing resin 40 as viewed in the z direction.

### Second Lead 12:

The second lead 12 is spaced apart from the first lead 11 (die pad portion 111) toward the second side in the x direction. The second lead 12 has the pad portion 121 and a plurality of second terminal portions 122.

The pad portion 121 has a second lead obverse surface 1211 and a second lead reverse surface 1212. The second lead obverse surface 1211 faces the first side in the z direction. The second lead reverse surface 1212 faces the second side in the z direction. The second lead obverse surface 1211 is connected to a connecting member 31. The shape of the pad portion 121 is not particularly limited. In the illustrated example, the pad portion 121 has a rectangular shape elongated in the y direction. As viewed in the z direction, the pad portion 121 is smaller than the die pad portion 111. Furthermore, the pad portion 121 is smaller than the die pad portion 111 in the z direction, and has the same size as the first portions 1121 in the z direction. In the illustrated example, the second lead obverse surface 1211 is located at the same position as the first lead obverse surface 1111 of the die pad portion 111 in the z direction.

The second terminal portions 122 are aligned in the y direction. Each of the second terminal portions 122 has a fourth portion 1221, a fifth portion 1222, and a sixth portion 1223.

The fourth portion 1221 is connected to the pad portion 121, extends from the pad portion 121 toward the second side in the x direction, and in the illustrated example, is parallel (or substantially parallel) to the xy plane. The shape of the fourth portion 1221 is not particularly limited, and in the illustrated example, is rectangular as viewed in the z direction.

The fifth portion 1222 is located on the first side in the z direction relative to the fourth portion 1221. The fifth portion 1222 is used when the semiconductor device A10 is surface-mounted on a circuit board or the like. The fifth portion 1222 extends in the x direction as viewed in the z direction.

The sixth portion 1223 is interposed between the fourth portion 1221 and the fifth portion 1222. The sixth portion 1223 extends from the fourth portion 1221 toward the first side in the z direction. In the illustrated example, the sixth portion 1223 is parallel (or substantially parallel) to the z direction. The shape of the sixth portion 1223 is not particularly limited, and in the illustrated example, is rectangular as viewed in the x direction.

The fifth portion 1222 extends from the sixth portion 1223 toward the first side in the x direction. In the illustrated example, the fifth portion 1222 is inclined to the x direction to become closer to the second side in the z direction as proceeding from the sixth portion 1223 toward the first side in the x direction. The fifth portion 1222 overlaps with the fourth portion 1221 as viewed in the z direction. The fifth portion 1222 also overlaps with the sealing resin 40 as viewed in the z direction.

### Third Lead 13:

The third lead 13 is spaced apart from the first lead 11 (die pad portion 111) toward the second side in the x direction. The third lead 13 is aligned with the second lead 12 in the y direction. The third lead 13 has a pad portion 131 and a third terminal portion 132.

The pad portion 131 has a third lead obverse surface 1311 and a third lead reverse surface 1312. The third lead obverse surface 1311 faces the first side in the z direction. The third lead reverse surface 1312 faces the second side in the z direction. The third lead obverse surface 1311 is connected to a connecting member 32. The shape of the pad portion 131 is not particularly limited, and in the illustrated example, is rectangular as viewed in the z direction. As viewed in the z direction, the pad portion 131 is smaller than the pad portion 121. Furthermore, the pad portion 131 is smaller than the die pad portion 111 in the z direction, and has the same size as the pad portion 121 in the z direction. In the illustrated example, the third lead obverse surface 1311 is located at the same position as the first lead obverse surface 1111 of the die pad portion 111 in the z direction.

The third terminal portion 132 has a seventh portion 1321, an eighth portion 1322, and a ninth portion 1323.

The seventh portion 1321 is connected to the pad portion 131, extends from the pad portion 131 toward the second side in the x direction, and in the illustrated example, is parallel (or substantially parallel) to the xy plane. The shape of the seventh portion 1321 is not particularly limited, and in the illustrated example, is rectangular as viewed in the z direction.

The eighth portion 1322 is located on the first side in the z direction relative to the seventh portion 1321. The eighth portion 1322 is used when the semiconductor device A10 is surface-mounted on a circuit board or the like. The eighth portion 1322 extends in the x direction as viewed in the z direction.

The ninth portion 1323 is interposed between the seventh portion 1321 and the eighth portion 1322. The ninth portion 1323 extends from the seventh portion 1321 toward the first side in the z direction. In the illustrated example, the ninth portion 1323 is parallel (or substantially parallel) to the z direction. The shape of the ninth portion 1323 is not particularly limited, and in the illustrated example, is rectangular as viewed in the x direction.

The eighth portion 1322 extends from the ninth portion 1323 toward the first side in the x direction. In the illustrated example, the eighth portion 1322 is inclined to the x direction to become closer to the second side in the z direction as proceeding from the ninth portion 1323 toward the first side in the x direction. The eighth portion 1322 overlaps with the seventh portion 1321 as viewed in the z direction. The eighth portion 1322 also overlaps with the sealing resin 40 as viewed in the z direction.

### Fourth Lead 14:

The fourth lead 14 is spaced apart from the first lead 11 (die pad portion 111) toward the second side in the x direction. The fourth lead 14 is located between the second lead 12 and the third lead 13 in the y direction. The fourth lead 14 has a pad portion 141 and a fourth terminal portion 142.

The pad portion 141 has a fourth lead obverse surface 1411 and a fourth lead reverse surface 1412. The fourth lead obverse surface 1411 faces the first side in the z direction. The fourth lead reverse surface 1412 faces the second side in the z direction. The fourth lead obverse surface 1411 is connected to a connecting member 33. The shape of the pad portion 141 is not particularly limited, and in the illustrated example, is rectangular as viewed in the z direction. As viewed in the z direction, the pad portion 141 is smaller than the pad portion 121 and has substantially the same size as the pad portion 131. Furthermore, the pad portion 141 is smaller than the die pad portion 111 in the z direction, and has the same size as each of the pad portion 121 and the pad portion 131 in the z direction. In the illustrated example, the fourth lead obverse surface 1411 is located at the same position as the first lead obverse surface 1111 of the die pad portion 111 in the z direction.

The fourth terminal portion 142 has a tenth portion 1421, an eleventh portion 1422, and a twelfth portion 1423.

The tenth portion 1421 is connected to the pad portion 141, extends from the pad portion 141 toward the second side in the x direction, and in the illustrated example, is parallel (or substantially parallel) to the xy plane. The shape of the tenth portion 1421 is not particularly limited, and in the illustrated example, is rectangular as viewed in the z direction.

The eleventh portion 1422 is located on the first side in the z direction relative to the tenth portion 1421. The eleventh portion 1422 is used when the semiconductor device A10 is surface-mounted on a circuit board or the like. The eleventh portion 1422 extends in the x direction as viewed in the z direction.

The twelfth portion 1423 is interposed between the tenth portion 1421 and the eleventh portion 1422. The twelfth portion 1423 extends from the tenth portion 1421 toward the first side in the z direction. In the illustrated example, the twelfth portion 1423 is parallel (or substantially parallel) to the z direction. The shape of the twelfth portion 1423 is not particularly limited, and in the illustrated example, is rectangular as viewed in the x direction.

The eleventh portion 1422 extends from the twelfth portion 1423 toward the first side in the x direction. In the illustrated example, the eleventh portion 1422 is inclined to the x direction to become closer to the second side in the z direction as proceeding from the twelfth portion 1423 toward the first side in the x direction. The eleventh portion 1422 overlaps with the tenth portion 1421 as viewed in the z direction. The eleventh portion 1422 also overlaps with the sealing resin 40 as viewed in the z direction.

### Semiconductor Element 20:

As shown in FIG. 4 and FIGS. 9 to 14, the semiconductor element 20 is mounted on the first lead obverse surface 1111 of the die pad portion 111. In the semiconductor device A10, the semiconductor element 20 is an n-channel metal-oxide-semiconductor field-effect transistor (MOSFET) having a vertical structure. The semiconductor element 20 is not limited to a MOSFET. The semiconductor element 20 may be another transistor such as an insulated gate bipolar transistor (IGBT). Furthermore, the semiconductor element 20 may be a diode. The semiconductor element 20 has a semiconductor layer 205, a first electrode 201, a second electrode 202, and a third electrode 203.

The semiconductor 205 a layer includes compound semiconductor substrate. The main material of the compound semiconductor substrate is silicon carbide (SiC). Alternatively, the main material of the compound semiconductor substrate may be silicon (Si).

The first electrode 201 is provided on a surface of the semiconductor layer 205 that faces the same side (first side) in the z direction as the side that the first lead obverse surface 1111 of the die pad portion 111 of the first lead 11 faces. The first electrode 201 corresponds to a source electrode of the semiconductor element 20.

The second electrode 202 is provided on a surface of the semiconductor layer 205 opposite to the first electrode 201 in the z direction. The second electrode 202 faces the first lead obverse surface 1111 of the die pad portion 111 of the first lead 11. The second electrode 202 corresponds to a drain electrode of the semiconductor element 20. In the present embodiment, the second electrode 202 is bonded to the first lead obverse surface 1111 via a bonding layer 29. The bonding layer 29 is solder, silver (Ag) paste, or calcined silver, for example.

The third electrode 203 is provided on the surface of the semiconductor layer 205 in the z direction where the first electrode 201 is provided, and is spaced apart from the first electrode 201. The third electrode 203 corresponds to a gate electrode of the semiconductor element 20. As viewed in the z direction, the area of the third electrode 203 is smaller than that of the first electrode 201.

### Connecting Members 31, 32, and 33:

The connecting member 31 is bonded to the first electrode 201 of the semiconductor element 20 and the second lead obverse surface 1211 of the pad portion 121 of the second lead 12. The material of the connecting member 31 is not particularly limited, and contains a metal such as aluminum (Al), copper (Cu), or gold (Au). The number of connecting members 31 is not particularly limited, and it is possible to provide a plurality of connecting members 31. In the illustrated example, the connecting member 31 is a flat band-like member containing aluminum (Al).

The connecting member 32 is connected to the third electrode 203 of the semiconductor element 20 and the third lead obverse surface 1311 of the pad portion 131 of the third lead 13. In the illustrated example, the connecting member 32 is a linear member narrower than the connecting member 31 and contains gold (Au).

The connecting member 33 is connected to the first electrode 201 of the semiconductor element 20 and the fourth lead obverse surface 1411 of the pad portion 141 of the fourth lead 14. In the illustrated example, the connecting member 33 is a linear member narrower than the connecting member 31 and contains gold (Au).

In the present embodiment, the first terminal portions 112 of the first lead 11 are drain terminals, the second terminal portions 122 of the second lead 12 are source terminals, the third terminal portion 132 of the third lead 13 is a gate terminal, and the fourth terminal portion 142 of the fourth lead 14 is a source sense terminal.

### Sealing Resin 40:

As shown in FIGS. 1 to 14, the sealing resin 40 covers the semiconductor element 20, the connecting members 31, 32, and 33, and a part of each of the first lead 11, the second lead 12, the third lead 13, and the fourth lead 14. The sealing resin 40 is electrically insulative. The sealing resin 40 is made of a material containing a black epoxy resin, for example. The sealing resin 40 has a first resin surface 41, a second resin surface 42, a third resin surface 43, a fourth resin surface 44, a fifth resin surface 45, a sixth resin surface 46, a first recess 471, and a second recess 472.

The first resin surface 41 faces the same side (the first side) in the z direction as the side that the first lead obverse surface 1111 of the die pad portion 111 of the first lead 11 faces. A second resin surface 42 faces the opposite side (the second side) from the first resin surface 41 in the z direction. The first lead reverse surface 1112 of the die pad portion 111 of the first lead 11 is exposed from the second resin surface 42. The second resin surface 42 and the first lead reverse surface 1112 are flush with each other.

The third resin surface 43 faces the first side in the x direction. In the present embodiment, the first portions 1121 of the first terminal portions 112 of the first lead 11 pass through the third resin surface 43. The first portions 1121 are spaced apart from the second resin surface 42 to the first side in the z direction. The first lead side surface 1113 of the die pad portion 111 is located on the second side in the x direction relative to the third resin surface 43, and is covered with the sealing resin 40.

The fourth resin surface 44 faces the opposite side (the second side) from the third resin surface 43 in the x direction. In the present embodiment, the fourth portions 1221 of the second terminal portions 122 of the second lead 12, the seventh portion 1321 of the third terminal portion 132 of the third lead 13, and the tenth portion 1421 of the fourth terminal portion 142 of the fourth lead 14 pass through the fourth resin surface 44.

The fifth resin surface 45 and the sixth resin surface 46 face away from each other in the y direction.

The first recess 471 is recessed from the first resin surface 41 to the second side in the z direction. The first recess 471 is open to the first side in the x direction, and is recessed from the third resin surface 43 to the second side in the x direction. In the illustrated example, the first recess 471 is connected to the fifth resin surface 45 and the sixth resin surface 46. However, the first recess 471 may not be connected to at least one of the fifth resin surface 45 and the sixth resin surface 46. At least a part of each second portion 1122 is accommodated in the first recess 471. At least a part of each second portion 1122 overlaps with the first recess 471 as viewed in the z direction. At least a part of each second portion 1122 overlaps with the first recess 471 as viewed in the x direction.

The second recess 472 is recessed from the first resin surface 41 to the second side in the z direction. The second recess 472 is open to the second side in the x direction, and is recessed from the fourth resin surface 44 to the first side in the x direction. In the illustrated example, the second recess 472 is connected to the fifth resin surface 45 and the sixth resin surface 46. However, the second recess 472 may not be connected to at least one of the fifth resin surface 45 and the sixth resin surface 46. At least a part of each fifth portion 1222 is accommodated in the second recess 472. At least a part of each fifth portion 1222 overlaps with the second recess 472 as viewed in the z direction. At least a part of each fifth portion 1222 overlaps with the second recess 472 as viewed in the x direction. At least a part of the eighth portion 1322 is accommodated in the second recess 472. At least a part of the eighth portion 1322 overlaps with the second recess 472 as viewed in the z direction. At least a part of the eighth portion 1322 overlaps with the second recess 472 as viewed in the x direction. At least a part of the eleventh portion 1422 is accommodated in the second recess 472. At least a part of the eleventh portion 1422 overlaps with the second recess 472 as viewed in the z direction. At least a part of the eleventh portion 1422 overlaps with the second recess 472 as viewed in the x direction.

FIG. 14 shows a use state of the semiconductor device A10. In this use example, the semiconductor device A10 is surface-mounted on a circuit board 92. In other words, the second portions 1122 of the first terminal portions 112, the fifth portions 1222 of the second terminal portions 122, the eighth portion 1322 of the third terminal portion 132, and the eleventh portion 1422 of the fourth terminal portion 142 are electrically connected to a wiring pattern (not illustrated) of the circuit board 92 by, for example, solder 921. A heat sink 91 is arranged to face the first lead reverse surface 1112 of the die pad portion 111. In the illustrated example, a sheet member 919 is provided between the first lead reverse surface 1112 and the heat sink 91. The sheet member 919 is an insulating sheet, for example.

Next, advantages of the semiconductor device A10 will be described.

As shown in FIG. 14, the first lead reverse surface 1112 is exposed from the second resin surface 42. This makes it possible to arrange the heat sink 91 to face the first lead reverse surface 1112 to dissipate heat from the semiconductor device A10 to the heat sink 91, for example. The second portions 1122 are located on the first side in the z direction relative to the first portions 1121. This makes it possible to surface-mount the semiconductor device A10 on the circuit board 92, for example, with use of the second portions 1122.

The second portions 1122 overlap with the sealing resin 40 as viewed in the z direction. This reduces the amount by which the first terminal portions 112 extend beyond the sealing resin 40 to the first side in the x direction. As a result, the mounting area for mounting the semiconductor device A10 can be reduced. Furthermore, the large sizes of the sealing resin 40, the die pad portion 111, the semiconductor element 20, etc., can be ensured with respect to the allowable mounting area.

The fifth portions 1222, the eighth portion 1322, and the eleventh portion 1422 overlap with the sealing resin 40 as viewed in the z direction. This reduces the amount by which each of the second terminal portions 122, the third terminal portion 132, and the fourth terminal portion 142 extends beyond the sealing resin 40 to the second side in the x direction. As a result, the mounting area for mounting the semiconductor device A10 can be reduced. Furthermore, the sizes of the sealing resin 40, the die pad portion 111, the semiconductor element 20, etc., can be increased with respect to the allowable mounting area.

At least a part of each second portion 1122 is accommodated in the first recess 471. This makes it possible to reduce the dimension of the semiconductor device A10 in the z direction. At least a part of each of the fifth portions 1222, the eighth portion 1322, and the eleventh portion 1422 is accommodated in the second recess 472. This makes it possible to reduce the dimension of the semiconductor device A10 in the z direction.

In the illustrated example, the second portions 1122 are inclined to the x direction to become closer to the second side in the z direction as proceeding from the third portions 1123 toward the second side in the x direction. As a result, when the semiconductor device A10 is mounted onto the circuit board 92, the connecting portions at which the second portions 1122 and the third portions 1123 are connected to each other are located closest to the circuit board 92. Even if the inclination angle of each second portion 1122 is varied due to an unavoidable error or the like during the manufacturing process, the connecting portions between the second portions 1122 and the third portions 1123 are likely to be located closest to the circuit board 92. As a result, the mounting posture of the semiconductor device A10 with respect to the circuit board 92 and the height of the semiconductor device A10 from the circuit board 92 in the z direction can be kept more constant.

In the illustrated example, the fifth portions 1222, the eighth portion 1322, and the eleventh portion 1422 are inclined to the x direction to become closer to the second side in the z direction as proceeding from the sixth portions 1223, the ninth portion 1323, and the twelfth portion 1423 toward the first side in the x direction. As a result, when the semiconductor device A10 is mounted onto the circuit board 92, the connecting portions at which the fifth portions 1222, the eighth portion 1322, and the eleventh portion 1422 are connected to the sixth portions 1223, the ninth portion 1323, and the twelfth portion 1423 are located closest to the circuit board 92. Even if the inclination angle of each of the fifth portions 1222, the eighth portion 1322, and the eleventh portion 1422 is varied due to an unavoidable error or the like during the manufacturing process, the connecting portions at which the fifth portions 1222, the eighth portion 1322, and the eleventh portion 1422 are connected to the sixth portions 1223, the ninth portion 1323, and the twelfth portion 1423 are likely to be located closest to the circuit board 92. As a result, the mounting posture of the semiconductor device A10 with respect to the circuit board 92 and the height of the semiconductor device A10 from the circuit board 92 in the z direction can be kept more constant.

The die pad portion 111 has the first terminal portions 112. This makes it possible to enhance the mounting strength of the semiconductor device A10.

The size of each first portion 1121 in the y direction is smaller than that of the die pad portion 111 in the y direction. This allows the sealing resin 40 to hold the first lead 11 more firmly.

The die pad portion 111 is larger than each first portion 1121 in the z direction. This makes it possible to transfer heat to a wider area in both the x direction and the y direction in the process of transferring heat from the semiconductor element 20 to the first lead reverse surface 1112. Thus, a wider area of each first portion 1121 can dissipate heat from the semiconductor element 20 to the heat sink 91 or the like, thereby enhancing heat dissipation efficiency.

One surface of each first portion 1121 is flush with the first lead obverse surface 1111. This makes it possible to increase the distance from the first portions 1121 to the second resin surface 42 in the z direction, thereby suppressing the interference between the heat sink 91, etc., and the first terminal portions 112.

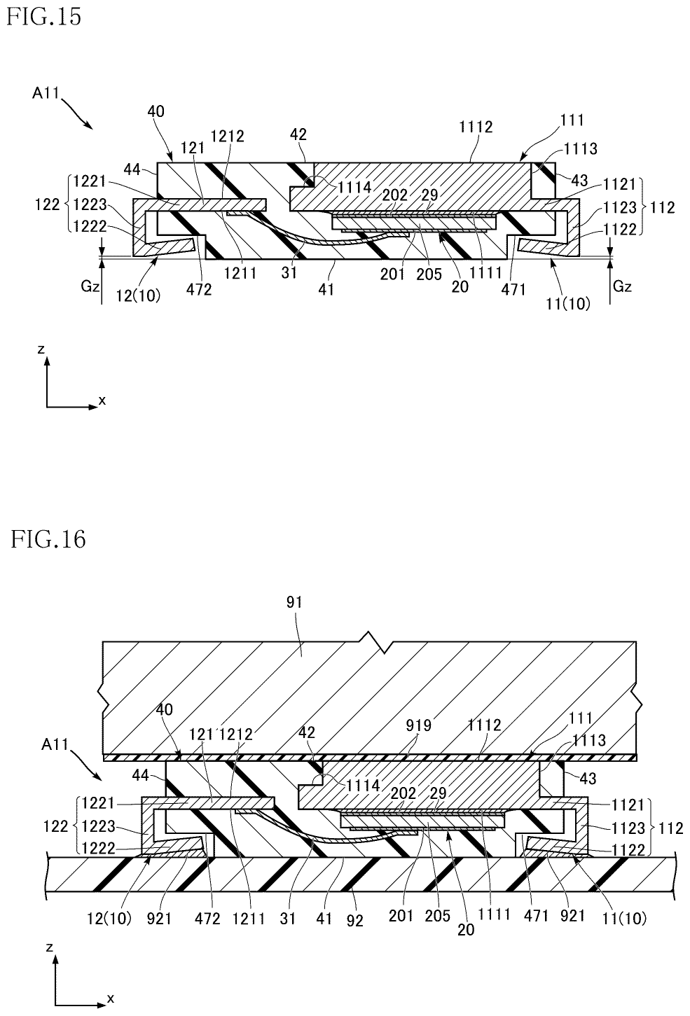

FIGS. 15 to 27 show other embodiments of the present disclosure. In these figures, elements that are the same as or similar to those in the above embodiment are provided with the same reference numerals as in the above embodiment. The configurations of the elements in each variation and each embodiment can be combined as appropriate as long as the combination does not cause technical contradictions.

### First Variation of the First Embodiment

FIGS. 15 and 16 show a first variation of the semiconductor device A10. In a semiconductor device A11 of the present variation, the second portions 1122, the fifth portions 1222, the eighth portion 1322, and the eleventh portion 1422 are located on the second side in the z direction (the side that the first lead reverse surface 1112 faces) relative to the first resin surface 41. In other words, all of the second portions 1122 overlap with the first recess 471 as viewed in the x direction. Furthermore, all of the fifth portions 1222, the eighth portion 1322, and the eleventh portion 1422 overlap with the second recess 472 as viewed in the x direction. The ends of the second portions 1122, the fifth portions 1222, the eighth portion 1322, and the eleventh portion 1422 on the first side in the z direction are spaced apart from the first resin surface 41 by a distance Gz.

According to the present variation, the semiconductor device A11 is surface-mountable and has the same advantages as the semiconductor device A10. The first resin surface 41 protrudes from the second portions 1122, the fifth portions 1222, the eighth portion 1322, and the eleventh portion 1422 toward the first side in the z direction by the distance Gz. Accordingly, in a use state of the semiconductor device A11 shown in FIG. 16, pressing the heat sink 91 against the semiconductor device A11 can easily bring the first resin surface 41 in contact with the circuit board 92. This makes it possible to prevent the force applied by the heat sink 91 from acting on the first lead 11, the second lead 12, the third lead 13, the fourth lead 14, and the semiconductor element 20.

### Second Variation of the First Embodiment

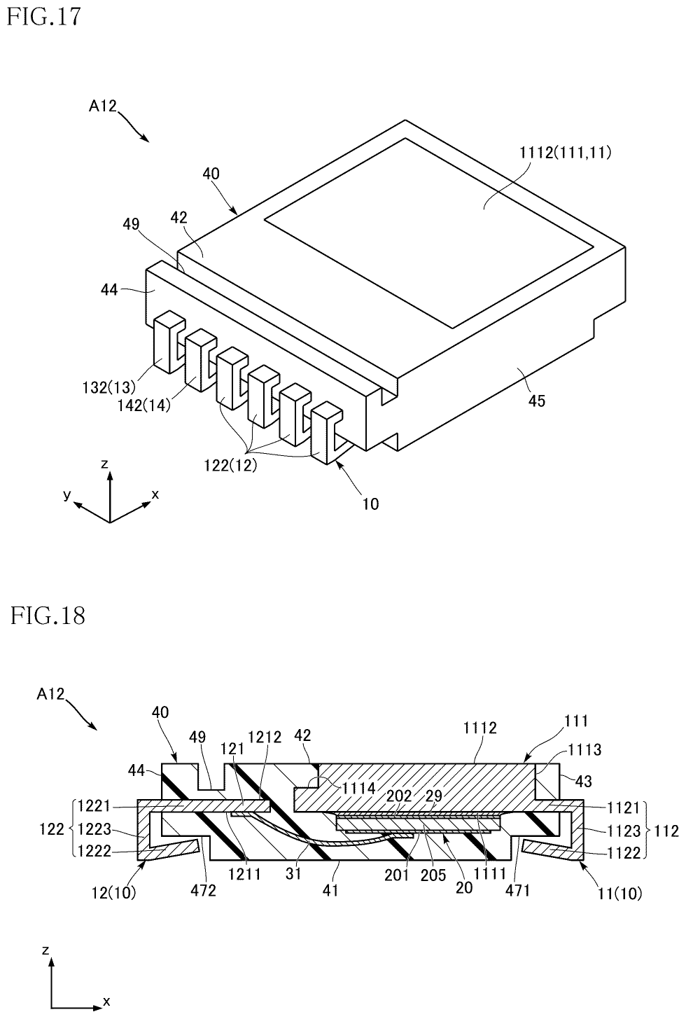

FIGS. 17 and 18 show a second variation of the semiconductor device A10. A semiconductor device A12 of the present variation has a groove 49 provided in the sealing resin 40.

The groove 49 is recessed from the second resin surface 42 in the z direction and extends in the y direction. The groove 49 reaches the fifth resin surface 45 and the sixth resin surface 46. The groove 49 is located between the first lead reverse surface 1112 and the fourth resin surface 44.

According to the present variation, the semiconductor device A12 is surface-mountable and has the same advantages as the semiconductor device A10. The sealing resin 40 is formed with the groove 49. This increases the distance along the surface of the sealing resin 40 (hereinafter, “creepage distance”) from the first lead reverse surface 1112 to each of the second lead 12 (the fourth portions 1221), the third lead 13 (the seventh portion 1321), and the fourth lead 14 (the tenth portion 1421).

### Third Variation of the First Embodiment

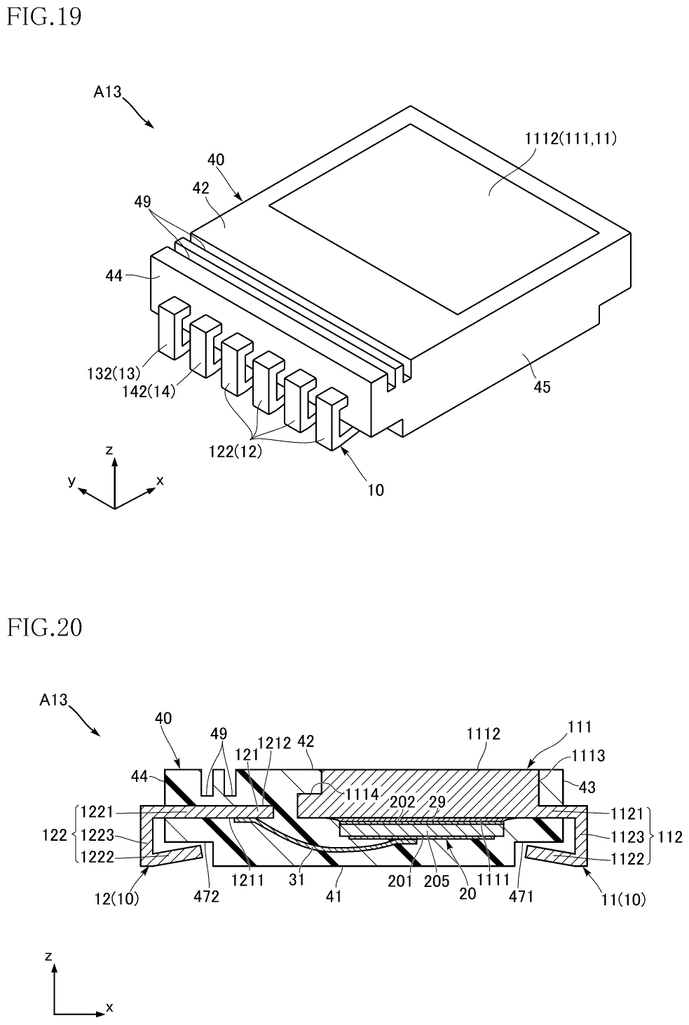

FIGS. 19 and 20 show a third variation of the semiconductor device A10. A semiconductor device A13 of the present variation has two grooves 49 provided in the sealing resin 40.

The grooves 49 extend in the y direction and reach the fifth resin surface 45 and the sixth resin surface 46. The two grooves 49 are spaced apart from each other in the x direction.

The present variation also allows surface-mounting of the semiconductor device A13 and achieves the same advantages as the above examples. The two grooves 49 can further increase the creepage distance between the first lead reverse surface 1112 and each of the second terminal portions 122, the third terminal portion 132, and the fourth terminal portion 142. As can be understood from the present variation, the number of grooves 49 is not particularly limited.

### Fourth Variation of the First Embodiment

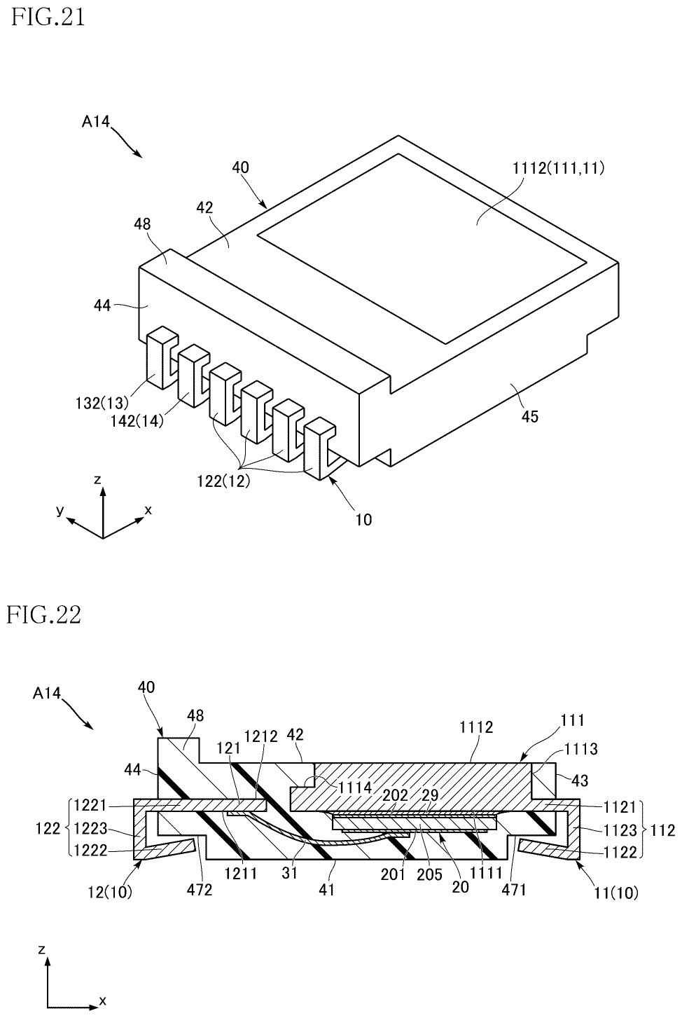

FIGS. 21 and 22 show a fourth variation of the semiconductor device A10. A semiconductor device A14 of the present variation has a protrusion 48 provided for the sealing resin 40.

The protrusion 48 protrudes from the second resin surface 42 to the second side in the z direction. The protrusion 48 extends in the y direction and reaches the fifth resin surface 45 and the sixth resin surface 46. In the illustrated example, the protrusion 48 is arranged at an end of the sealing resin 40 on the second side in the x direction, and is in contact with the fourth resin surface 44.

The present variation also allows surface-mounting of the semiconductor device A14. The protrusion 48 can increase the creepage distance between the first lead reverse surface 1112 and each of the second terminal portions 122, the third terminal portion 132, and the fourth terminal portion 142.

### Fifth Variation of the First Embodiment

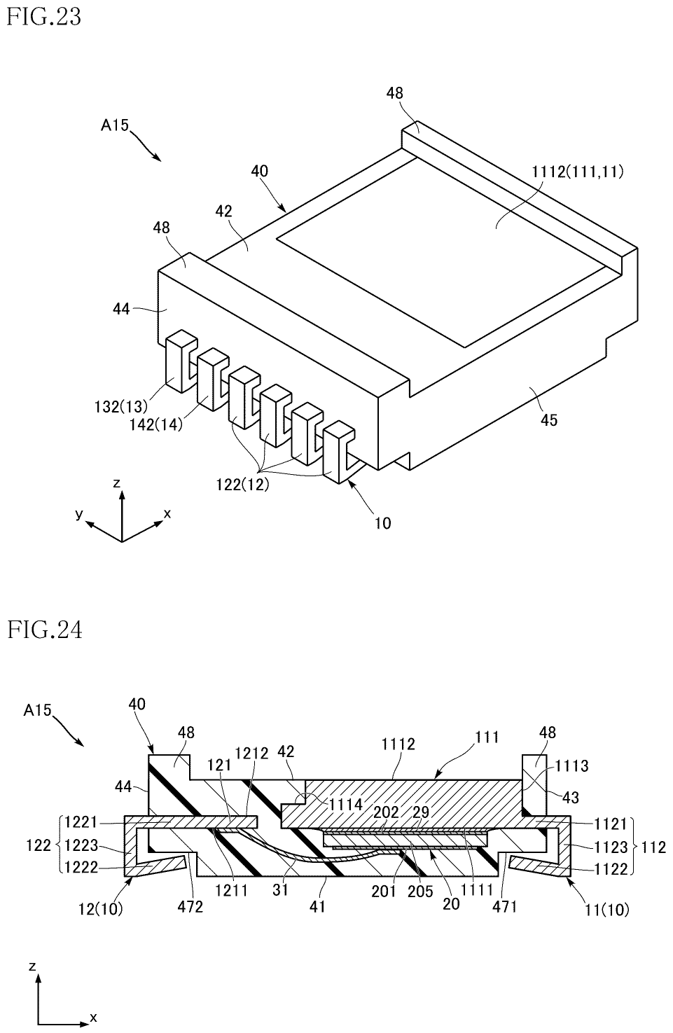

FIGS. 23 and 24 show a fifth variation of the semiconductor device A10. A semiconductor device A15 of the present variation has two protrusions 48 provided for the sealing resin 40.

The protrusions 48 protrude to the second side in the z direction. The protrusions 48 extend in the y direction and reach the fifth resin surface 45 and the sixth resin surface 46. The two protrusions 48 are spaced apart from each other with the first lead reverse surface 1112 therebetween in the x direction. One of the protrusions 48 is in contact with the fourth resin surface 44. The other protrusion 48 is in contact with the third resin surface 43.

The present variation also allows surface-mounting of the semiconductor device A15. Furthermore, with the two protrusions 48, an external object can be more accurately positioned with respect to the elements of the semiconductor device A15 such as the first lead reverse surface 1112. As can be understood from the present variation, the number of protrusions 48 is not particularly limited.

### Second Embodiment

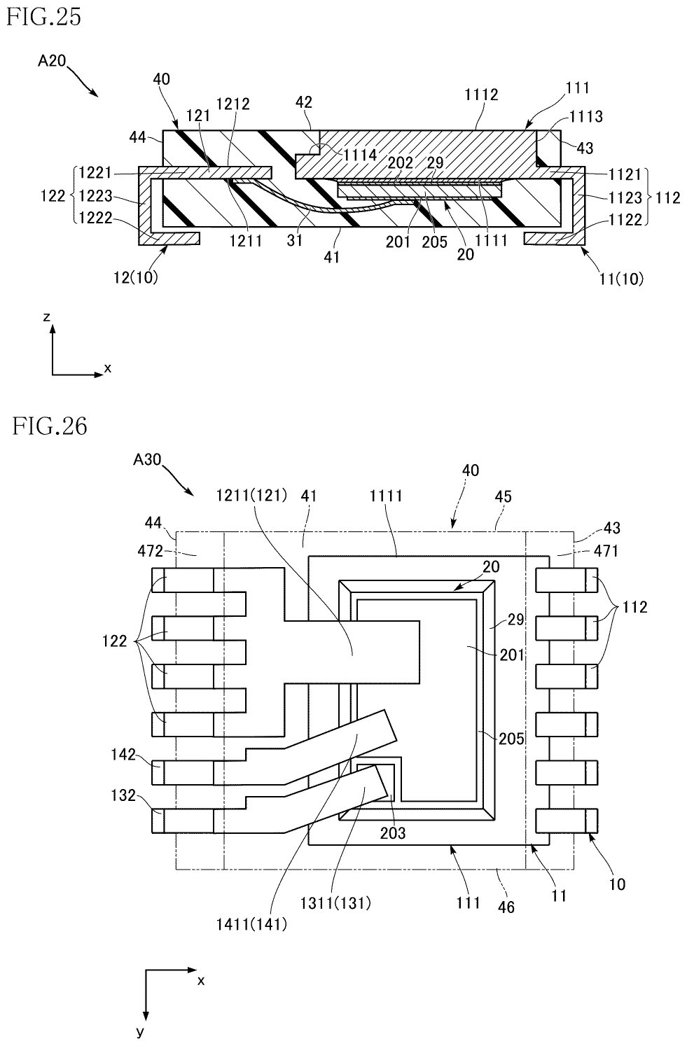

FIG. 25 shows a semiconductor device according to a second embodiment of the present disclosure. A semiconductor device A20 in the present embodiment is different from the semiconductor device in the above embodiment in that the sealing resin 40 does not have the first recess 471 or the second recess 472.

In the present embodiment, the second resin surface 42 is connected to the third resin surface 43 and the fourth resin surface 44. A part of each of the second portions 1122, the fifth portions 1222, the eighth portion 1322, and the eleventh portion 1422 overlaps with the second resin surface 42 as viewed in the z direction. The second portions 1122, the fifth portions 1222, the eighth portion 1322, and the eleventh portion 1422 are located on the first side in the z direction relative to the second resin surface 42. The second portions 1122, the fifth portions 1222, the eighth portion 1322, and the eleventh portion 1422 do not overlap with the sealing resin 40 as viewed in the x direction.

The present embodiment also allows surface-mounting of the semiconductor device A20. Furthermore, since a part of each of the second portions 1122, the fifth portions 1222, the eighth portion 1322, and the eleventh portion 1422 overlaps with the sealing resin 40 as viewed in the z direction, the mounting area of the semiconductor device A20 in the x direction can be reduced.

### Third Embodiment

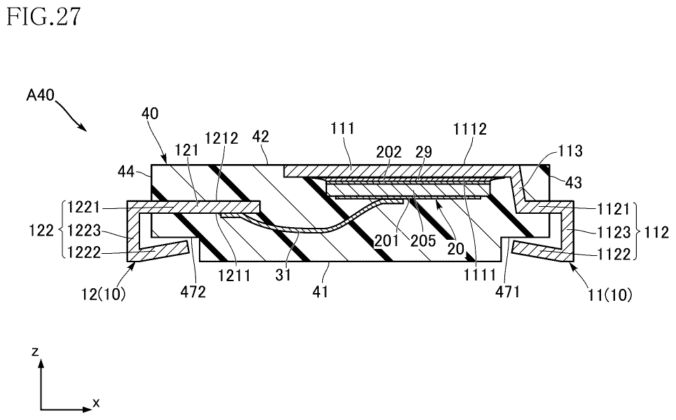

FIG. 26 shows a semiconductor device according to a third embodiment of the present disclosure. A semiconductor device A30 according to the present embodiment does not include any of the connecting members 31, 32, and 33 described above.

In the present embodiment, the second lead reverse surface 1212 of the pad portion 121 of the second lead 12 is electrically connected to the first electrode 201 of the semiconductor element 20. The third lead reverse surface 1312 of the pad portion 131 of the third lead 13 is electrically connected to the third electrode 203 of the semiconductor element 20. The fourth lead reverse surface 1412 of the pad portion 141 of the fourth lead 14 is electrically connected to the first electrode 201 of the semiconductor element 20.

The present embodiment also allows surface-mounting of the semiconductor device A30. As can be understood from the present embodiment, the second lead 12, the third lead 13, and the fourth lead 14 may be electrically connected to the semiconductor element 20 in various manners.

### Fourth Embodiment

FIG. 27 shows a semiconductor device according to a fourth embodiment of the present disclosure. A semiconductor device A40 in the present embodiment is different from those in the above embodiments in the configuration of the first lead 11.

The first lead 11 of the present embodiment is configured such that the die pad portion 111 and each of the first portions 1121 have the same (or substantially the same) size in the z direction. The first lead 11 has a connecting portion 113. The connecting portion 113 connects the die pad portion 111 and the first portions 1121 of the first terminal portions 112 to each other. The first portions 1121 pass through the third resin surface 43 and are spaced apart from the second resin surface 42 on the first side in the z direction. In the present embodiment, the position of the first lead obverse surface 1111 in the z direction is different from the position of the surface of each first portion 1121 facing the first side in the z direction and the positions of the second lead obverse surface 1211, the third lead obverse surface 1311, and the fourth lead obverse surface 1411 in the z direction.

The present embodiment also allows surface-mounting of the semiconductor device A40. As can be understood from the present embodiment, the relationship between the size of the die pad portion 111 in the z direction and the size of each first portion 1121 in the z direction is not particularly limited.

The semiconductor device according to the present disclosure is not limited to the embodiments described above. Various design changes can be made to the specific configurations of the elements of the semiconductor device according to the present disclosure. The present disclosure includes the embodiments described in the following clauses.

### Clause 1

A semiconductor device comprising:
a semiconductor element;
a first lead including a die pad portion and a first terminal portion, the die pad portion including a first lead obverse surface that faces a first side in a thickness direction and on which the semiconductor element is mounted and a first lead reverse surface that faces a second side in the thickness direction; and
a sealing resin including a first resin surface facing the first side in the thickness direction, a second resin surface facing the second side in the thickness direction, and a third resin surface facing a first side in a first direction perpendicular to the thickness direction, the sealing resin covering the semiconductor element and a portion of the die pad portion,
wherein the first lead reverse surface is exposed from the second resin surface,
the first terminal portion includes a first portion extending outward from the third resin surface to the first side in the first direction, a second portion located on the first side in the thickness direction relative to the first portion and used for mounting, and a third portion interposed between the first portion and the second portion, and
the second portion overlaps with the sealing resin as viewed in the thickness direction.

### Clause 2

The semiconductor device according to clause 1, wherein the second portion extends from the third portion toward a second side in the first direction.

### Clause 3

The semiconductor device according to clause 1 or 2, wherein the third portion extends from the first portion toward the first side in the thickness direction.

### Clause 4

The semiconductor device according to any of clauses 1 to 3, wherein the first lead reverse surface is flush with the second resin surface.

### Clause 5

The semiconductor device according to any of clauses 1 to 4, wherein
the sealing resin includes a first recess recessed from the first resin surface in the thickness direction and open to the first side in the first direction, and
at least a part of the second portion is accommodated in the first recess.

### Clause 6

The semiconductor device according to any of clauses 1 to 4, wherein at least a part of the second portion overlaps with the second resin surface as viewed in the thickness direction.

### Clause 7

The semiconductor device according to any of clauses 1 to 6, wherein the die pad portion is larger than the first portion of the first terminal portion in the thickness direction.

### Clause 8

The semiconductor device according to clause 7, wherein one side of the first portion is flush with the first lead obverse surface.

### Clause 9

The semiconductor device according to any of clauses 1 to 8, further comprising:
a connecting member connected to the semiconductor element; and
a second lead located on the second side in the first direction relative to the first lead, and including a pad portion that includes a second lead obverse surface facing the first side in the thickness direction,
wherein the connecting member is connected to the second lead obverse surface.

### Clause 10

The semiconductor device according to clause 9,
wherein the sealing resin includes a fourth resin surface facing the second side in the first direction,
the second lead includes a second terminal portion that includes a fourth portion extending outward from the fourth resin surface to the second side in the first direction, a fifth portion located on the first side in the thickness direction relative to the fourth portion and used for mounting, and a sixth portion interposed between the fourth portion and the fifth portion, and
the fifth portion overlaps with the sealing resin as viewed in the thickness direction.

### Clause 11

The semiconductor device according to clause 10, wherein the fifth portion extends from the sixth portion toward the first side in the first direction.

### Clause 12

The semiconductor device according to clause 10 or 11, wherein the sixth portion extends from the fourth portion toward the first side in the thickness direction.

### Clause 13

The semiconductor device according to any of clauses 10 to 12, wherein
the sealing resin includes a second recess recessed from the first resin surface in the thickness direction and open to the second side in the first direction, and
at least a part of the fifth portion is accommodated in the second recess.

### Clause 14

The semiconductor device according to any of clauses 10 to 12, wherein at least a part of the fifth portion overlaps with the second resin surface as viewed in the thickness direction.

### Clause 15

The semiconductor device according to any of clauses 10 to 14, wherein the first lead obverse surface and the second lead obverse surface are located at a same position in the thickness direction.

### Clause 16

The semiconductor device according to any of clauses 1 to 15, wherein the sealing resin includes a groove recessed from the second resin surface in the thickness direction.

### Clause 17

The semiconductor device according to any of clauses 1 to 16, wherein the sealing resin includes a protrusion protruding from the second resin surface in the thickness direction.

### REFERENCE NUMERALS

A10, A11, A12, A13, A14, A15, A20, A30, A40: Semiconductor device
10: Conductive member 11: First lead
12: Second lead 13: Third lead
14: Fourth lead 20: Semiconductor element
29: Bonding layer 30: Semiconductor element
31: Connecting member 32: Connecting member
33: Connecting member 40: Sealing resin
41: First resin surface 42: Second resin surface
43: Third resin surface 44: Fourth resin surface
45: Fifth resin surface 46: Sixth resin surface
48: Protrusion 49: Groove
52: Resin reverse surface 91: Heat sink
92: Circuit board 111: Die pad portion
112: First terminal portion 113: Connecting portion
121: Pad portion 122: Second terminal portion
131: Pad portion 132: Third terminal portion
141: Pad portion 142: Fourth terminal portion
201: First electrode 202: Second electrode
203: Third electrode 205: Semiconductor layer
471: First recess 472: Second recess
919: Sheet member 921: Solder
1111: First lead obverse surface
1112: First lead reverse surface
1113: First lead side surface 1114: First intermediate surface
1121: First portion 1122: Second portion
1123: Third portion 1211: Second lead obverse surface
1212: Second lead reverse surface 1221: Fourth portion
1222: Fifth portion 1223: Sixth portion
1311: Third lead obverse surface 1312: Third lead reverse surface
1321: Seventh portion 1322: Eighth portion
1323: Ninth portion 1411: Fourth lead obverse surface
1412: Fourth lead reverse surface 1421: Tenth portion
1422: Eleventh portion 1423: Twelfth portion
Gz: Distance

1. A semiconductor device comprising:
a semiconductor element;
a first lead including a die pad portion and a first terminal portion, the die pad portion including a first lead obverse surface that faces a first side in a thickness direction and on which the semiconductor element is mounted and a first lead reverse surface that faces a second side in the thickness direction; and
a sealing resin including a first resin surface facing the first side in the thickness direction, a second resin surface facing the second side in the thickness direction, and a third resin surface facing a first side in a first direction perpendicular to the thickness direction, the sealing resin covering the semiconductor element and a portion of the die pad portion,
wherein the first lead reverse surface is exposed from the second resin surface,
the first terminal portion includes a first portion extending outward from the third resin surface to the first side in the first direction, a second portion located on the first side in the thickness direction relative to the first portion and used for mounting, and a third portion interposed between the first portion and the second portion, and
the second portion overlaps with the sealing resin as viewed in the thickness direction.

2. The semiconductor device according to claim 1, wherein the second portion extends from the third portion toward a second side in the first direction.

3. The semiconductor device according to claim 1, wherein the third portion extends from the first portion toward the first side in the thickness direction.

4. The semiconductor device according to claim 1, wherein the first lead reverse surface is flush with the second resin surface.

5. The semiconductor device according to claim 1, wherein
the sealing resin includes a first recess recessed from the first resin surface in the thickness direction and open to the first side in the first direction, and
at least a part of the second portion is accommodated in the first recess.

6. The semiconductor device according to claim 1, wherein at least a part of the second portion overlaps with the second resin surface as viewed in the thickness direction.

7. The semiconductor device according to claim 1, wherein the die pad portion is larger than the first portion of the first terminal portion in the thickness direction.

8. The semiconductor device according to claim 7, wherein one side of the first portion is flush with the first lead obverse surface.

9. The semiconductor device according to claim 1, further comprising:
a connecting member connected to the semiconductor element; and
a second lead located on the second side in the first direction relative to the first lead, and including a pad portion that includes a second lead obverse surface facing the first side in the thickness direction,
wherein the connecting member is connected to the second lead obverse surface.

10. The semiconductor device according to claim 9,
wherein the sealing resin includes a fourth resin surface facing the second side in the first direction,
the second lead includes a second terminal portion that includes a fourth portion extending outward from the fourth resin surface to the second side in the first direction, a fifth portion located on the first side in the thickness direction relative to the fourth portion and used for mounting, and a sixth portion interposed between the fourth portion and the fifth portion, and
the fifth portion overlaps with the sealing resin as viewed in the thickness direction.

11. The semiconductor device according to claim 10, wherein the fifth portion extends from the sixth portion toward the first side in the first direction.

12. The semiconductor device according to claim 10, wherein the sixth portion extends from the fourth portion toward the first side in the thickness direction.

13. The semiconductor device according to claim 10, wherein
the sealing resin includes a second recess recessed from the first resin surface in the thickness direction and open to the second side in the first direction, and
at least a part of the fifth portion is accommodated in the second recess.

14. The semiconductor device according to claim 10, wherein at least a part of the fifth portion overlaps with the second resin surface as viewed in the thickness direction.

15. The semiconductor device according to claim 10, wherein the first lead obverse surface and the second lead obverse surface are located at a same position in the thickness direction.

16. The semiconductor device according to claim 1, wherein the sealing resin includes a groove recessed from the second resin surface in the thickness direction.

17. The semiconductor device according to claim 1, wherein the sealing resin includes a protrusion protruding from the second resin surface in the thickness direction.
